(19) United States
(12) Patent Application Publication
(10) Pub. No.: US 2002/0027952 A1
(43) Pub. Date: Mar. 7, 2002

(54) Method for automatic equalization for use in demodulating a digital multilevel modulation signal and automatic equalization circuit and receiver circuit using the method

(76) Inventors: Yoshiro Kokuryo, Tachikawa (JP); Nobuo Tsukamoto, Akishima (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/945,693

(22) Filed: Sep. 5, 2001

(30) Foreign Application Priority Data
Sep. 7, 2000 (JP) 2000-270964

(51) Int. Cl. H03H 7/30; H03H 7/40; H03K 5/159

(52) U.S. Cl. 375/230

(57) ABSTRACT

An automatic equalization method, automatic equalization circuit, demodulation circuit or receiver circuit for automatically updating an equalization characteristic required to demodulate a received signal including a training signal of a predetermined pattern transmitted from a transmission side apparatus. First, tap coefficients of an automatic equalizer for data reproduction are initial-set on the basis of received training signal. After the initial-setting, the tap coefficients are updated once every N symbols (where N is an integer of at least unity) of the received signal by using the received signal. The received signal is equalized in the automatic equalizer for data reproduction based the updated tap coefficients. The equalized received signal is demodulated.

### CROSS REFERENCE TO RELATED APPLICATIONS

The present application relates to U.S. patent application Ser. No. 09/819,709 assigned to the same assignee of the present invention, filed on Mar. 29, 2001 in the name of Yoshiro Kokuryo, Nobuo Tsukamoto and Hiroyuki Hamazumi and entitled “AUTOMATIC EQUALIZATION CIRCUIT AND RECEIVER CIRCUIT USING THE SAME”.

### BACKGROUND OF THE INVENTION

The present invention relates to an equalization circuit in a demodulation circuit for demodulating a digital modulation signal, especially digital multilevel QAM signal. In particular, the present invention relates to an automatic equalization method and an automatic equalization circuit for automatically setting an equalization characteristic of a transmission path by using a training signal and a data signal, and a receiver circuit (demodulation circuit) using the automatic equalization circuit.

In any transmission system, including a signal transmission system based on a digital modulation system, especially digital multilevel QAM system, it is the best thing to make waveform distortion, echo, or the like on the transmission path, as small as possible. Thus, conventionally, it has been known to apply an automatic equalizer to a demodulation circuit (receiver circuit) of a digital modulation system, especially digital multilevel QAM system.

For example, such applications are disclosed by SHAHID U. H. QURESHI “ADAPTIVE EQUALIZATION” PROCEEDINGS OF THE IEEE, VOL. 73, NO. 9, SEPTEMBER 1985, pages 1349 and 1355; KAZUO MURANO and SHIGEYUKI UNAKAMI “DIGITAL SIGNAL PROCESSING IN INFORMATION/COMMUNICATION”, SHOKODO CO., LTD., NOV. 25, 1987, FIG. 2.24 in page 57; and THE INSTITUTE OF ELECTRONICS AND COMMUNICATION ENGINEERS OF JAPAN “APPLICATION OF DIGITAL SIGNAL PROCESSING”, THE INSTITUTE OF ELECTRONICS AND COMMUNICATION ENGINEERS OF JAPAN, MAY 20 1981, FIG. 6.1 in page 150 and FIG. 6.21 in page 171.

### SUMMARY OF THE INVENTION

An automatic equalization circuit of such a system as to receive a data signal and a training signal for automatic equalizer alternately and automatically updating and setting an equalization characteristic required for data signal demodulation on the basis of a received training signal is described in U.S. Ser. No. 09/819,709 assigned to the same assignee of the present invention.

In this automatic equalization circuit, an automatic equalizer for data reproduction properly and another automatic equalizer for equalization are provided. When a training signal is received, it is successively stored in a memory once and successively read out at predetermined timing. On the basis of the training signal thus read out and a reference training signal generated on the reception apparatus side, tap coefficients for setting the equalization characteristic against the transmission path are updated by using the automatic equalizer for equalization training. By successively repeating updated results of the tap coefficients in the automatic equalizer for data reproduction, the tap coefficients for setting the equalization characteristic against the transmission path required for data signal reproduction are updated.

Operation of this automatic equalization circuit will now be described by referring to a timing chart of FIG. 5.

In FIG. 5, a training signal DT and a data signal DA of received data shown in (a) of FIG. 5 are provided with numbers 0, 1, 2, . . . So as to correspond thereto, a training signal DT and a data signal DA shown in (f) of FIG. 5 are also provided with numbers 0, 1, 2, . . . In (a) and (f) of FIG. 5, signals having the same number correspond to each other.

In (a) of FIG. 5, a frame comprised of a training signal DT1 in a period X having a time length tt and a data signal DA1 in a following period Y having a time length td is transmitted alternatively from a transmission apparatus side, and received on the reception apparatus side.

If the frame of (a) of FIG. 5 is received by the reception apparatus side, then signals Ir and Qr, which are an in-phase component (I component) and a quadrature component (Q component) for the training signal DT1 in the period X lasting from time t0 to time t1, are successively stored in a memory once as shown in (b) of FIG. 5. At the same time, the signals Ir and Qr are subject to a delay of just one frame and supplied to the automatic equalizer for data reproduction as signals IrD and QrD shown in (f) of FIG. 5.

Subsequently, as shown in (b1) of FIG. 5, signals Ir′ and Qr′ of the training signal DT1 stored in the memory are read out at predetermined timing. The signals Ir′ and Qr′ become an equalization signal subjected to equalization processing in the automatic equalizer for equalization training. By using an equalization error signal obtained by deriving a difference between the equalization signal and a reference training signal generated on the reception apparatus side serving as a reference signal of tap coefficient update processing, tap coefficient update processing of the equalization characteristic of the transmission path is conducted. As shown in (c) of FIG. 5, this tap coefficient update processing is conducted on a training signal DT having a number MT of symbols (where MT is an integer satisfying the relation 1<MT) in a period ts, and updated tap coefficients Ct1 are obtained. In a subsequent period X lasting from time t2 to time t3, signals Ir and Qr of the received training signal DT2 are stored in the memory to provide for update processing of the tap coefficients for equalizing the next data signal DA2.

The tap coefficients Ct1 updated in the tap coefficient update processing is set in the automatic equalizer for data immediately before the time t3. The signals IrD and QrD of the data signal DA1 shown in (f) of FIG. 5 are equalized by the automatic equalizer for data reproduction on the basis of the tap coefficients Ct1, then identified, and reproduced as the data signal DA1 transmitted from the transmission apparatus side.

Thereafter, in the same way, on the basis of periodically inserted training signals DT2, DT3, . . . and the reference training signal generated on the reception apparatus side which is a reference signal of the tap coefficient update processing, tap coefficients are obtained in the tap coefficient update processing by the automatic equalizer for training signal. The tap coefficients thus obtained are set in the automatic equalizer for data reproduction at predetermined timing. Thus, data signals DA2, DA3, . . . are equalized and data are reproduced.

In the above described automatic equalization circuit, tap coefficient update is conducted in the automatic equalizer for equalization training on the basis of the training signal DT periodically inserted in the received data and the training signal generated on the reception apparatus side which is a reference signal of the tap coefficient update processing. The data signal DA is subjected to equalization processing using the tap coefficients in the automatic equalizer for data reproduction, and reproduced as data supplied from the transmission side apparatus. In this equalization processing, the tap coefficients are updated and set by using the training signal on the assumption that the transmission path characteristic during the transmission period of the training signal is the same as that during the transmission period of the data signal. The data signal following the training signal is equalized by using the tap coefficients.

The condition of the transmission path meeting such an assumption is that a fading phenomenon or the like causing degradation of the transmission path characteristic varies gently during the training signal DT, the variation can be regarded as nearly the same (the transmission path characteristic is the same) during the training signal DT, and the data transmission rate is faster than the variation. Under such a condition, even the above described automatic equalization circuit can sufficiently equalize the transmission path characteristic and reproduce the data reliably.

If a signal in data transmission is affected by a fast fading phenomenon (i.e., the fading phenomenon varies faster than one frame time), however, then the transmission characteristic during the transmission period of the training signal DT and the transmission characteristic during the transmission period of the data signal DA vary respectively, and the transmission characteristics during both transmission periods cannot be regarded as the same. In such a case, the data signal DA is equalized by tap coefficients updated in a period of the training signal DT so as to correspond to the transmission characteristic in the transmission period of the training signal DT. The data signal DA is not equalized by tap coefficients updated so as to correspond to variation of the transmission characteristic in the transmission period of the data signal DA.

Therefore, tap coefficient update processing following the variation of the transmission path characteristic is not conducted. Equalization becomes insufficient, and the received signal cannot be reproduced correctly. Thus, a probability of occurrence of errors in reproduced data becomes high.

An object of the present invention is to provide an automatic equalization method and an automatic equalization circuit in digital multilevel signal demodulation capable of improving data error probability by updating tap coefficients of an automatic equalizer so as to follow the variation of the transmission path characteristic, and provide a receiver circuit (demodulation circuit) using the automatic equalization circuit.

In accordance with the present invention, the above described object is achieved by conducting equalization on the transmission path characteristic by using tap coefficients derived by tap coefficient update processing from the training signal included in received data (received signal) in the automatic equalizer for equalization training of the aforementioned U.S. Ser. No. 09/819,709, then conducting tap coefficient update processing by using received data once every N (where N is an integer satisfying the relation 1≦N) symbols of the received data, and subsequently conducting processing of equalizing on the transmission path characteristic on the basis of a result thereof.

To be concrete, the following improvements have been applied to the automatic equalization circuit of U.S. Ser. No. 09/819,709.

(1) An equalized signal equalized in the automatic equalizer for equalization training is identified and an identified signal is generated.

(2) A reference training pattern signal corresponding to a training signal sent from the transmission side apparatus is generated.

(3) By conducting signal mapping on the identified signal of (1) or the reference training pattern signal of (2), signals of an in-phase component and a quadrature component are generated as reference signals of tap coefficient update processing.

(4) By selectively conducting switchover between the identified signal of (1) or the reference training pattern signal of (2), the reference signal of (3) is obtained.

(5) In a period during which tap coefficient update processing is executed by using the training signal of the received data (received signal) and the reference training pattern signal of (2), the training signal of received data is selected as the reference signal of (3). In a subsequent period, the identified signal of (1) is selected as the reference signal of (3).

In addition, the following improvement has been made.

(6) On the basis of the training signal of the received data, and the reference training pattern signal of (2) generated on the reception apparatus side serving as the reference signal of the tap coefficient update processing, tap coefficients are derived in the automatic equalizer for equalization training. The tap coefficients are set in the automatic equalizer for data reproduction. Operation conducted until then is the same. Thereafter, the ensuing operation is conducted.

That is, an equalized signal obtained by equalizing the data signal of received data (received signal) in the automatic equalizer for equalization training is identified in an identification circuit. By using an identified signal obtained as a result thereof, as the reference signal of tap coefficient update processing, and on the basis of the tap coefficients derived in (6) by using the training signal, tap coefficient update processing of the automatic equalizer for equalization training is conducted once every N symbols. And updated tap coefficients are set as tap coefficients of the automatic equalizer for data reproduction. Such a series of tap coefficient update processing is continued by using the identified signal of the data signal of the received data as the reference signal of the tap coefficient update processing.

If the transmission symbol rate becomes fast, however, the operation rate of hardware for implementing the tap coefficient update processing and equalization processing cannot be disregarded. If the operation rate of the hardware becomes sufficiently fast, then tap coefficient update using an identified signal that is identified every symbol becomes possible. If the operation rate of the hardware is slow, however, tap coefficient update is continued at a rate of once every N symbols (where N is an integer satisfying the relation 1<N).

For example, in the case where the modulation rate is 13.5 Mbaud and a training signal having MT=256 symbols and a data signal of MA=18944 symbols are included in a frame (19200 symbols MT+MA=256+18944), it takes, in the automatic equalization circuit of U.S. Ser. No. 09/819,709, a period of one frame to conduct the tap coefficient update processing and equalization processing using the training signal of 256 symbols. If hardware having the same operation state is used, the data signal of received data is equalized in the automatic equalizer, and an identified signal is used as a reference signal of tap coefficient update processing, then tap coefficient update at a rate of once every 75 symbols (=19200 symbols÷256 symbols) becomes possible.

In the automatic equalization circuit of U.S. Ser. No. 09/819,709, the tap coefficient update processing is conducted every frame. Once tap coefficients are set in the automatic equalizer for equalization training, however, thereafter tap coefficient update processing is conducted once every N symbols (N=75 symbols in the above described example) in the present invention. Therefore, tracking of tap coefficients for variation of the characteristic of the transmission path becomes very fine.

Further, if the operation rate of the hardware becomes sufficiently fast in the future, then tap coefficient updating at a rate of once per N=1 symbol becomes possible, and the tracking of the tap coefficients for the variation of the characteristic of the transmission path is extremely improved.

### BRIEF DESCRIPTION OF THE DRAWINGS

The foregoing and other objects, features and advantages of the invention will be apparent from the following more particular description of the embodiments of the invention as illustrated in the accompanying drawings wherein:

FIG. 1 is a block diagram showing a configuration of a demodulation circuit (receiver circuit) including an automatic equalization circuit of a first embodiment according to the present invention;

FIG. 2 is a timing chart showing operation of a demodulation circuit of FIG. 1;

FIG. 3 is a block diagram showing a configuration of a demodulation circuit (receiver circuit) including an automatic equalization circuit of a second embodiment according to the present invention;

FIG. 4 is a timing chart showing operation of a demodulation circuit of FIG. 3;

FIG. 5 is a timing chart showing operation of an automatic equalization circuit of U.S. Ser. No. 09/819,709;

FIG. 6 is a block diagram showing a demodulation circuit of a prior technique;

FIG. 7 is a block diagram showing an example of an automatic equalizer included in a demodulation circuit of a digital multilevel signal;

FIG. 8 is a block diagram showing an example of a transversal filter which is a component of an automatic equalizer shown in FIG. 7;

FIG. 9 is a block diagram showing a configuration of a demodulation circuit of U.S. Ser. No. 09/819,709; and

FIG. 10 is a timing chart showing operation of a demodulation circuit shown in FIG. 9.

### DESCRIPTION OF THE EMBODIMENTS

Prior to description of embodiments, an automatic equalization circuit of a prior technique and an automatic equalization circuit of U.S. Ser. No. 09/819,709 will now be described in more detail.

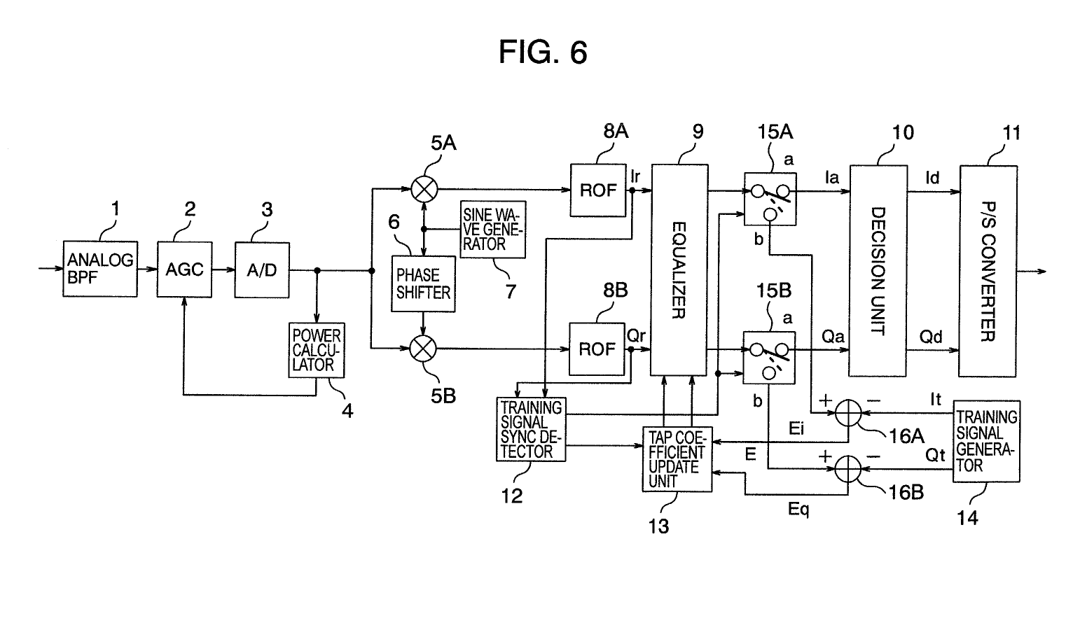

FIG. 6 is a block diagram showing an example of a demodulation circuit (receiver circuit) including an automatic equalization circuit according to a prior technique of a digital multilevel modulation system.

In the demodulation circuit shown in FIG. 6, a received modulated wave signal of a carrier frequency f is first supplied to an analog BPF (Band Pass Filter) 1. After subjected to band width restriction in the analog BPF 1, the signal is adjusted to a fixed level by an AGC (Automatic Gain Control portion) 2 regardless of the level with which the signal is received. Then, the signal is supplied to an A/D converter (analog to digital converter) 3 so as to be converted into a digital signal. The digital signal is supplied to a received signal power calculation portion 4 and multipliers 5A and 5B.

Then, the received signal power calculation portion 4 calculates the level of the received signal on the basis of the digital signal supplied from the A/D converter 3. The AGC gain level is fed back to the control input of the AGC 2 by calculating and compare to the reference level. Thus, a digital signal consequently having a fixed level is supplied to the A/D converter 3.

The digital signal supplied to the multipliers 5A and 5B is multiplied in the multipliers 5A and 5B respectively by a carrier signal of a frequency f supplied from a sine wave generator 7. Then, an in-phase component (I component) and a quadrature component (Q component) are extracted.

At this time, the carrier signal is supplied to the multiplier 5A directly from the sine wave generator 7 while the carrier signal which is phase-shifted by π/2 in a phase shifter 6 is supplied to the multiplier 5B. Thus, quadrature or orthogonal demodulation is carried out.

Here, the sine wave signal supplied to the multiplier 5A is expressed by cos(ωt) and the sine wave signal supplied to the multiplier 5B is expressed by sin(ωt).

Incidentally, ω=2 πf.

The in-phase component (I component) and the quadrature component (Q component) supplied from the multipliers 5A and 5B are wave-shaped by roll-off filters (ROFs) 8A and 8B, respectively, and extracted as output signals Ir and Qr, respectively. The output signals Ir and Qr are supplied to an equalizer 9 the equalization characteristics of which can be set up.

Then, data signals Ia and Qa equalized by the equalizer 9 are supplied to a decision unit 10. The decision unit 10 judges a transmission point sent from the transmission apparatus side. Results of this judgement are outputted as data signals Id and Qd. The data signals Id and Qd are converted into a serial signal by a P/S converter (Parallel-In Serial-Out Shift Register) 11. Thus, demodulated reception data is obtained.

Here, the equalizer 9 has a function of equalizing a received signal so as to eliminate influence of waveform distortion, echo, or the like, which may be given to a transmission signal on a transmission path. It is therefore necessary to set predetermined equalization characteristics on the equalizer 9 beforehand.

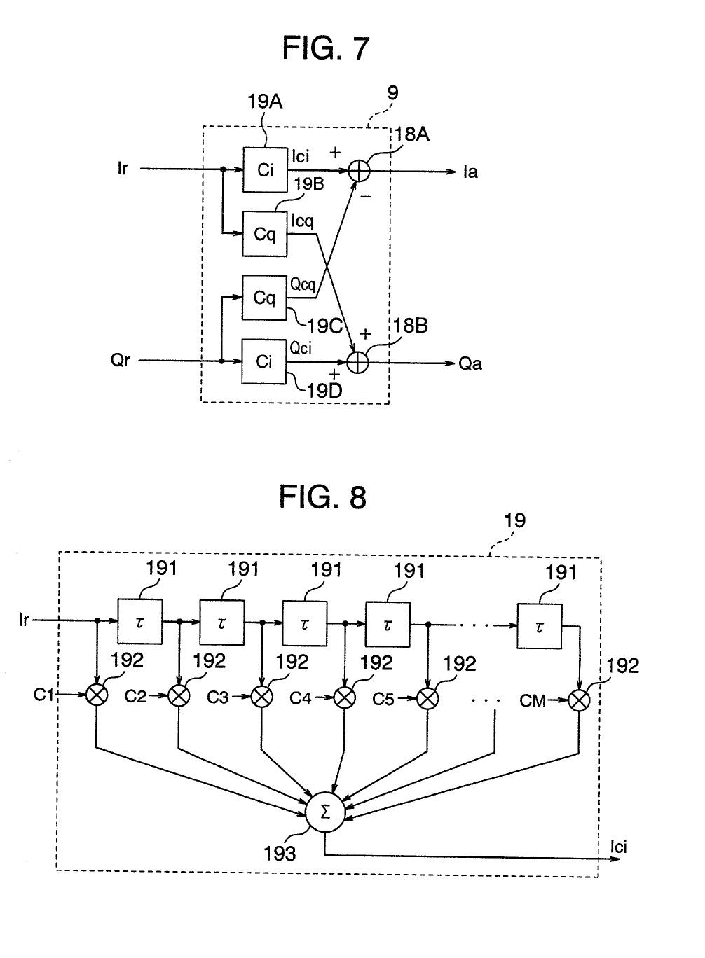

Here, the equalizer 9 is generally designed to carry out operation with a complex number comprised of an in-phase component and a quadrature component. An example of such an equalizer 9 will be described with reference to FIG. 7.

The equalizer 9 shown in FIG. 7 is constituted by two adders 18A and 18B and four transversal filters 19A to 19D. The inputs and outputs of the equalizer 9 has a relation as follows.

Now, assume that respective tap coefficients of the respective transversal filters 19A to 19D are Ci and Cq as shown in FIG. 7. Further, assume that the values of the input signals Ir and Qr are expressed by Ir and Qr. Then, the relation among the value (Ir+j·Qr) of the input signal expressed by a complex signal number and the tap coefficients Ci and Cq can be expressed by:

(Ir+j·Qr)·(Ci+j·Cq)=(Ir·Ci−Qr·Cq)+j·(Ir·Cq+Qr·Ci)

Accordingly, the values of the output signals Ia and Qa can be expressed by the input signals Ir and Qr and the tap coefficients Ci and Cq as follows.

Ia=Ir·Ci−Qr·Cq

Qa=Ir·Cq+Qr·Ci

Thus, the characteristics of the output signals Ia and Qa with respect to the input signals Ir and Qr, that is, the transmission characteristics can be changed by changing the tap coefficients Ci and Cq.

Here, each of the transversal filters 19A to 19D of the equalizer 9 is generally constituted by (M1) delay elements 191, M multipliers 192 and an adder 193 as shown in FIG. 8. The transmission characteristics of each of the transversal filters 19A to 19D are established by coefficients C1 to CM set in the multipliers 192, respectively. These coefficients are called tap coefficients. The equalization characteristics of the equalizer 9 are set by updating the tap coefficients.

Thus, the setting of the equalization characteristics is carried out as follows.

That is, a signal called a training signal having a predetermined format (for example, the same format as a training signal sent from the transmission apparatus side) is set as a reference signal in advance. Before the data transmission is started, the training signal is first made to be sent from the transmission apparatus side to the reception apparatus side. Thus, the above described equalization characteristics are set by use of the training signal. After the equalization characteristics have been set up, transmission of the data signal is carried out in earnest.

At this time, on the reception apparatus side, the received training signal is compared with a training signal generated in a training signal generator 14. The difference between the received training signals and the generated training ones is regarded as an error. The tap coefficients of the equalizer 9 are changed sequentially in accordance with the error. Thus, the equalizer 9 can almost equalize the distortion of the transmission path when the error becomes smallest.

To this end, a training signal synchronization detector 12, switch circuits 15A and 15B, and adders 16A and 16B are provided as shown in FIG. 6.

The training signal synchronization detector 12 may be formed by a correlator. An M-sequence PN pattern is generally used for the training signal. A part of the PN pattern is set as coefficients of the correlator. The output signals Ir and Qr respectively of the roll-off filters 8A and 8B are supplied to the correlator so that the correlation is detected. If the patterns coincide with each other, a large correlation value is outputted. Conversely, if there is no correlation, that is, if the patterns do not coincide with each other, a small correlation value is outputted. The output of the correlator is compared with a predetermined threshold value by a comparator not shown. When the output exceeds the threshold value of the comparator, it can be considered that a predetermined pattern of the training signal has been received. It is known beforehand where the specific pattern is located in the training signal. Thus, the frame layout of the received signal is found. As a result, the head position of the training signal will be found after the next frame.

Now, when the training signal is received and detected by the training signal synchronization detector 12, the switch circuits 15A and 15B are changed over to the contact b side respectively. At the same time, a detection signal is supplied to the tap coefficient update unit 13 so as to start to change the equalization characteristics as mentioned above.

As a result, when the training signal transmitted from the transmission apparatus side is being detected on the reception apparatus side, the output signals Ia and Qa of the equalizer 9 are supplied to the adders 16A and 16B. At this time, training signals It and Qt having the same format as the training signal generated on the transmission apparatus side are supplied from the training signal generator 14 to the subtraction inputs of the adders 16A and 16B respectively.

Then, equalization error signals Ei and Eq which are differences between the outputs Ia and Qa of the equalizer 9 and the reference training signals It and Qt respectively are extracted from the outputs of the adders 16A and 16B. Thus, the tap coefficient update unit 13 receives these output signals of the adders 16A and 16B as the equalization error signals Ei and Eq so as to update the tap coefficients of the equalizer 9 sequentially in accordance with an equalization processing algorithm based on a predetermined least mean square method.

The tap coefficients means coefficients C1 to CM provided for the above described M multipliers 192 shown in FIG. 8. The respective tap coefficients C1 to CM are updated to minimize an equalization error value E in accordance with the following equation. Thus, the output signals Ia and Qa provided with required equalization can be obtained.

CM^{(T+1)}=CM^{(T)}−g·X*·E

X*: conjugate complex number of inputted signals=Ir−j·Qr

E: Ei+j·Eq=(Ia−Id)+j·(Qa−Qd)

g: constant (scalar)

CM^{(T)}: tap coefficients C1 to CM at time T

CM^{(T+1}): tap coefficients C1 to CM at time T+1

wherein j designates an imaginary part of complex number.

Incidentally, the algorithm for setting the equalization characteristics is known well in the art. For example, the details thereof are disclosed in HIROSHI MIYAKAWA et al. “DIGITAL SIGNAL PROCESSING”, edited by THE INSTITUTE OF ELECTRONICS AND COMMUNICATION ENGINEERS OF JAPAN, November 1975, pages 231-243.

The processing for updating tap coefficient values by the tap coefficient update unit 13 is carried out repeatedly in a period of 1/modulation rate. Thus, the equalization errors Ei and Eq are reduced sequentially, coming close to zero.

Accordingly, the equalization errors Ei and Eq take values small enough to eliminate influence of waveform distortion or the like which may be produced in accordance with the conditions of the transmission path. Thus, a signal received on the reception apparatus side is equalized by the equalizer 9 so that correct data can be reproduced and the almost optimum equalization characteristics can be obtained.

If such equalization characteristics can be obtained thus on the reception apparatus side, then the switch circuits 15A and 15B are changed over back to the contact a side respectively. Thus, the reception apparatus side shifts to operation for data transmission. At this time, on the transmission apparatus side, however, there is no way to know the point in time when the setting of the equalization characteristics is finished on the reception apparatus side.

Therefore, conventionally, in anticipation of time necessary for setting the equalization characteristics by use of a training signal on the reception apparatus side, a time length to send out the training signal is determined in advance. If the time has passed, the transmission apparatus side stops sending the training signal and shifts to the operation for data transmission.

Then, when the training signal thus finishes, the end of the training is detected by the training signal synchronization detector 12 on the reception apparatus side. In response thereto, the switch circuits 15A and 15B are changed over to the contact a side.

Accordingly, the data signals Ia and Qa are thereafter supplied to the decision unit 10. As a result, the reception apparatus side shifts to its ordinary data transmission operation so that a serial data signal is outputted from the P/S converter 11.

However, in the above described conventional automatic equalization technique, no consideration is given to reduction in the data transmission efficiency due to transmitting no data while the transmission of the training signal. Thus, there is a problem that the data transmission error and the transmission efficiency have a so-called trade-off relationship in accordance with the transmission frequency of the training signal. That is, if one of the data transmission error and the transmission efficiency is suppressed, the other increases.

As described above, when the data signal DA is transmitted, the transmission is divided into sections every period Y, and the training signal DT is inserted between the sections. Here, in a period X when the training signal DT is transmitted, the data signal DA which is supposed to be transmitted cannot be transmitted. Thus, the data transmission efficiency is lowered correspondingly by the frequency of the transmission of the training signal DT.

U.S. Ser. No. 09/819,709 discloses a digital multilevel signal demodulation circuit capable of sufficiently improving the transmission efficiency while suppressing data transmission errors.

Hereafter, the demodulation circuit disclosed in U.S. Ser. No. 09/819,709 will be described.

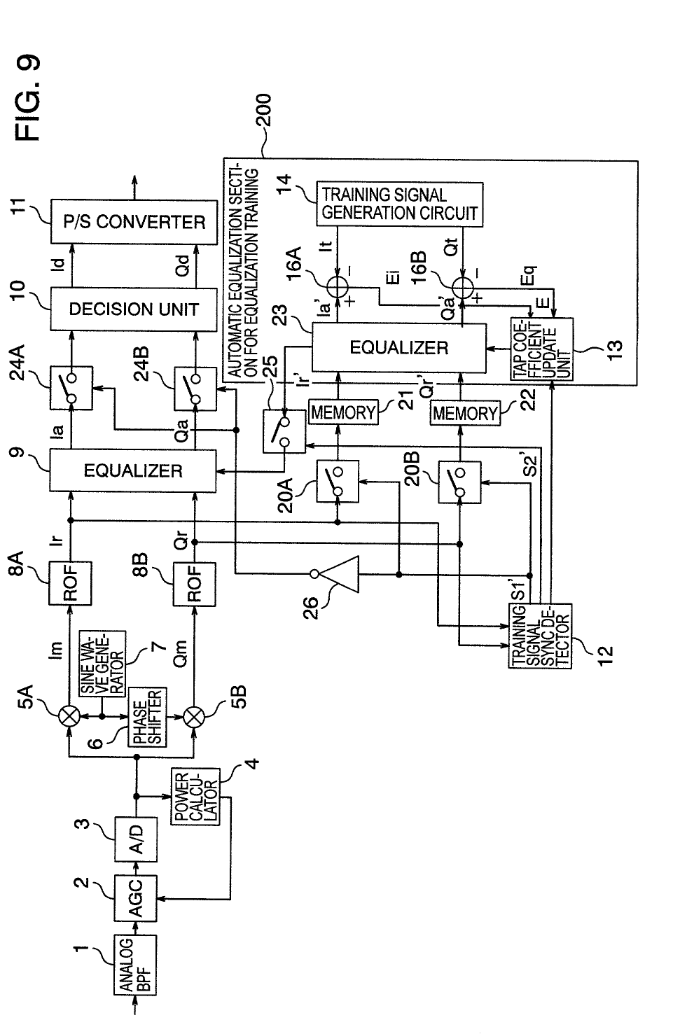

FIG. 9 is a block diagram showing a configuration of the demodulation circuit disclosed in U.S. Ser. No. 09/819,709.

The embodiment shown in FIG. 9 has a first different point from the circuit shown in FIG. 6 as follows. That is, if a training signal appears in the outputs of the roll-off filters 8A and 8B, the training signal is once stored in memories 21 and 22. To this end, switch circuits 20A and 20B are provided.

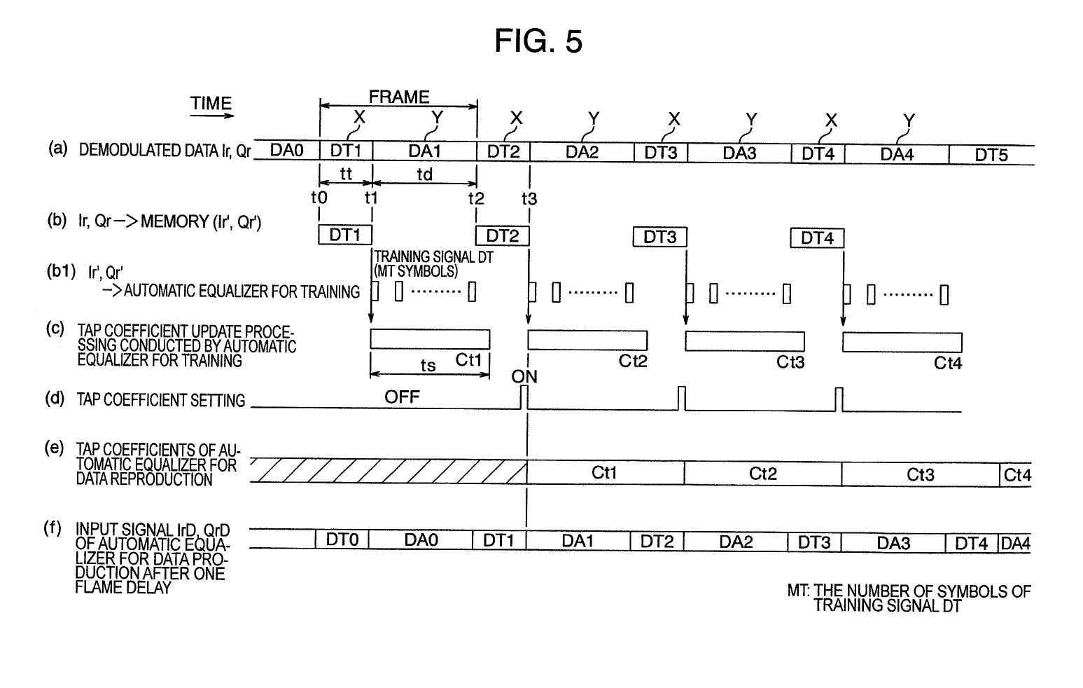

Next, the embodiment shown in FIG. 9 has a second different point from the circuit shown in FIG. 6 as follows. That is, an equalizer 23 for equalization training having the same arrangement as the data-reproducing equalizer 9 is provided separately from the equalizer 9. The two equalizers are provided not because of the above-explained trade-off relationship between the data transmission error and the transmission efficiency, but because of the fact that the data transmission rate is high whereas the speed of the hardware implementing the tap coefficient update processing is low, resulting in a slow execution of the tap coefficient update processing (ideally one execution per symbol which is impossible to do in this case) as shown in FIG. 5 wherein it takes the time ts (Ct) to update the tap coefficients based on the training signal DT. That is the reason why the equalizer 23 for equalization training is necessary other than the equalizer for data reproduction. The tap coefficient update unit 13, adders 16A and 16B and the training signal generator circuit 14 are connected to the equalizer 23 so as to constitute an equalization training automatic equalization portion 200. Incidentally, this classification is merely expedient. For example, the memories 21 and 22 may be included in the equalization training automatic equalization portion 200.

First, the training signal read out from the memories 21 and 22 is supplied to the equalizer 23 at a predetermined point of time. The tap coefficient update unit 13 is operated to update the tap coefficients of the equalizer 23 until a predetermined equalization condition can be obtained.

As a result of such training processing by the equalizer 23, the tap coefficients are updated so that the predetermined equalization condition is obtained. Then, the tap updating result is given to the equalizer 9. At this point in time, the tap coefficients of the equalizer 9 are set so that a resulted equalization condition can be obtained.

To this end, switch circuits 24A and 24B, on one hand, are provided. By the switch circuits 24A and 24B, output signals Ia and Qa of the equalizer 9 are separated from the inputs of the decision unit 10 while the training signal is being received. On the other hand, a switch 25 is also provided. By the switch 25, the tap coefficient setting result set on the equalizer 23 is given to the equalizer 9 at a predetermined point in time.

Accordingly, the switch circuits 20A and 20B are controlled by the training signal synchronization detector 12 to be closed only while the training signal is being detected. In an opposite relation with the switch circuits 20A and 20B, the switch circuits 24A and 24B are controlled by the existence of an inversion circuit 26 so as to be opened only while the training signal is being detected.

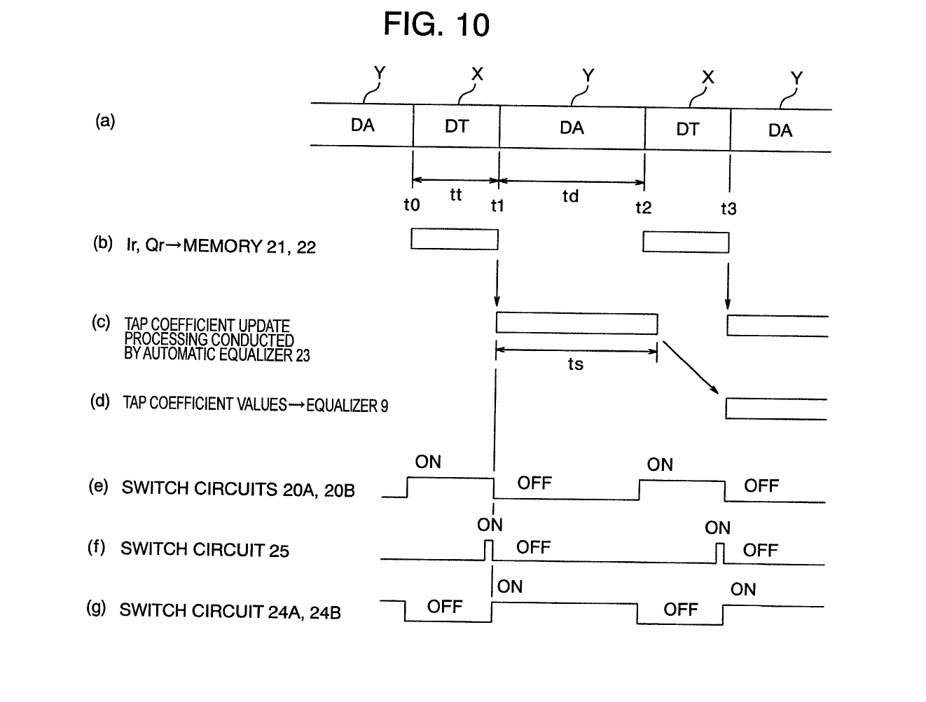

Next, description will be made about the operation of the embodiment shown in FIG. 9 by referring to a timing chart of FIG. 10.

First, in this embodiment, in the same manner as in FIG. 5, a training signal DT and a data signal DA are transmitted alternately periodically in a period tt and in a period td, respectively, on the transmission apparatus side.

Accordingly, when data transmission operation is started, the training signal DT and the data signal DA are received alternately as shown in (a) of FIG. 10.

Here, a period X designates a period when the training signal DT is being received, and a period Y designates a period when the data signal DA is being received.

Then, the training signal synchronization detector 12 operates in accordance with the received signals shown in (a) of FIG. 10 as follows. That is, as shown in (e) of FIG. 10, the training signal synchronization detector 12 generates a control signal S1′ which turns ON when the training signal DT is being detected and which turns OFF while the data signal DA is being received. Further, the detector 12, as shown in (f) of FIG. 10, generates a control signal S2′ so that the control signal S2′ is made to be ON in a pulse-like fashion immediately before the control signal S1′ turns OFF from ON.

Thus, the respective switch circuits have operation timings respectively just as shown in (e), (f) and (g) of FIG. 10.

First, the switch circuits 20A and 20B are turned ON at the time t0 as shown in (e) of FIG. 10.

As a result, in the period X when the training signal DT is being received, output signals Ir and Qr respectively of the roll-off filters 8A and 8B are supplied to the memories 21 and 22, respectively. Thus, the training signal DT is stored in the memories 21 and 22 from the time t0.

At this time, the training signal synchronization detector 12 receives the output signals Ir and Qr respectively of the roll-off filters 8A and 8B. While the training signal DT is being received, the training signal synchronization detector 12 stores the output signals Ir and Qr respectively of the roll-off filters 8A and 8B respectively into the memories 21 and 22 synchronously with the training signal DT as shown in (b) of FIG. 10.

On the other hand, at this time, output signals Ia and Qa of the equalizer 9 can not be supplied to the decision unit 10 because the switch circuits 24A and 24B are turned OFF, as shown in (g) of FIG. 10.

Next, following the period X, in the period Y when the next data signal DA is being received, first, the tap coefficient update unit 13 starts to operate at illustrated time t1 in response to instructions from the training signal synchronization detector 12. Then, as shown in (c) of FIG. 10, the tap coefficient update unit 13 can carry out the tap updating processing with data signals Ir′ and Qr′ read out from the memories 21 and 22 in a period ts regardless of the length of the period DT, differently from the above described operation shown in FIG. 5. Thus, the training processing is carried out by the equalizer 23.

Then, the tap coefficients are updated by the tap coefficient update unit 13 until tap coefficients minimizing the error between the output signals Ia′ and Qa′ of the equalizer 23 and reference training signals It and Qt are obtained. The output signals Ia′ and Qa′ are obtained based on the data signals Ir′ and Qr′ of the training signal DT read out from the memories 21 and 22 at this time, while the reference training signals It and Qt are supplied from the training signal generator 14. Each of the error becomes smallest when the processing time ts has passed. Thus, the processing of updating the tap coefficients is terminated.

In addition, in this period Y, the switch circuits 24A and 24B are turned ON as shown in (g) of FIG. 10. Thus, the output signals Ia and Qa of the equalizer 9 are supplied directly to the identifying unit 10. As a result, data demodulated from the data signal DA from the time t1 is outputted from the P/S converter 11.

Then, at time t3, that is, at a time after the transmission of the training signal DT from the time t2 is terminated and immediately before the next period Y starts, the switch circuit 25 is closed again for a short time as shown in (f) of FIG. 10. By this time t3, updating of the tap coefficients by use of the equalizer 23 has been finished as shown in (c) of FIG. 10.

At this time, the tap coefficient updating result is set in the equalizer 9 through the switch circuit 25. As a result, the data signal DT subjected to correct equalization by the equalizer 9 is then demodulated and outputted from the P/S converter 11.

Then, after the time t3, the above described operation from the time t1 to the time t3 is repeated again.

Thus, in the demodulation circuit in FIG. 9, whenever the training signal DT appears, the tap coefficients of the equalizer 23 are updated by the just preceding training signal DT. This tap coefficient updating result is given to the equalizer 9 whenever the just succeeding training signal DT appears. Thus, such tap coefficient updating operation is repeated.

As a result, even if the equalizer 9 is in the diverged condition during data transmission and bit errors are caused in data transmission, the bit errors will be limited till the next training signal DT is received. After the next training signal is received, error-free correct data can be reproduced again as received data.

In this demodulation circuit, as is apparent from FIG. 10, it is found that the tap coefficient updating time ts carried out by the tap coefficient update unit 13 is not limited to be within the reception period tt of the training signal DT but can be made longer than the reception period tt. The tap coefficient updating time ts may be longer than the transmission period td of the data signal DA so as to have a length close to the sum of those periods (tt+td).

When the training signal DT stored in the memories 21 and 22 are read out therefrom as the data signals Ir′ and Qr′, the read-out rate may be made to meet the updating rate with which the tap coefficient update unit 13 updates the tap coefficients. Accordingly, even if the updating rate with which the tap coefficient update unit 13 updates the tap coefficients is so slow that the tap coefficients cannot be updated by the throughput in the transmission period tt of the training signal DT, it is possible to deal with such a case sufficiently without any problem.

The length of the period for the training signal depends, in principle, on an equalization algorithm. Generally, however, the length is rather determined on the basis of the length of the processing time of the tap coefficients taken by the hardware implementing the equalization algorithm. However, according to the automatic equalization circuit of FIG. 9, the period tt for the training signal DT can be shortened regardless of the updating time ts even if the updating time ts is long. As a result, although the transmission period tt of the training signal DT cannot be made shorter than the length determined in accordance with the equalization algorithm, but it can be made much shorter than the transmission period td of the data signal DA.

As a result, the transmission period tt of the training signal DT can be shortened sufficiently in accordance with the data modulation rate without being limited by the tap coefficient updating rate which is carried out by the tap coefficient update unit 13. Thus, the transmission efficiency can be improved sufficiently.

Hereafter, embodiments of the present invention will be described by referring to the drawing. The same components are denoted by like reference characters.

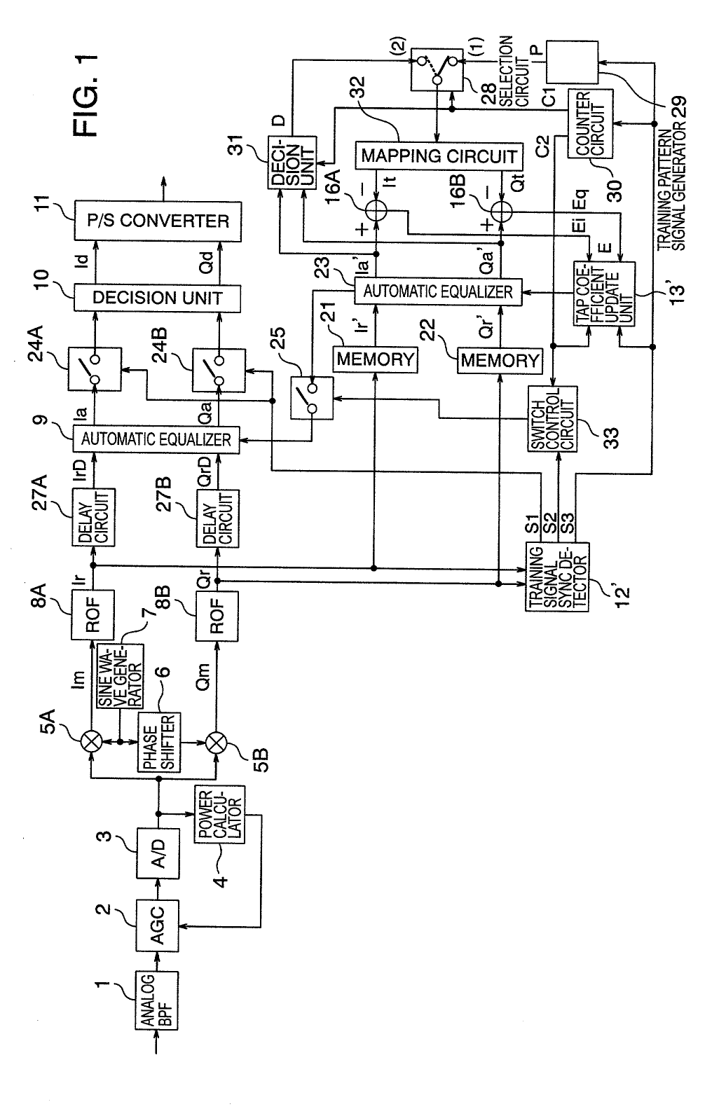

FIG. 1 is a block diagram showing an example of a demodulation circuit (receiver circuit) including an automatic equalization circuit of a digital multilevel modulation system according to an embodiment of the present invention.

In FIG. 1, a configuration ranging from an analog BPF (bandpass filter) 1 to a P/S converter (parallel/serial converter) 11 through delay circuits 27A and 27B and an automatic equalizer 9 for data reproduction is the same as that of the automatic equalization circuit of the aforementioned U.S. Ser. No. 09/819,709. Its operation will now be described.

First, a received modulated wave signal having a carrier frequency f is input to an analog BPF1, band-limited therein, made constant in level irrespective of the level when received, by an AGC (automatic gain control) section 2, input to an A/D converter (analog-digital converter) 3, digitized therein, and supplied to a received power calculator 4 and multipliers 5A and 5B.

In the received power calculator 4, the level of the received signal is calculated on the basis of the digital signal output from the A/D converter 3. The calculated level is fed back to a control input of the AGC 2. As a result, an analog signal eventually made to have a fixed level is input to the A/D converter 3.

The digital signal supplied to the multipliers 5A and 5B is multiplied therein by a carrier signal having a frequency f supplied from a sine wave generator 7. Signals of an in-phase component (I component) and a quadrature component (Q component) are thus taken out.

At this time, the multiplier 5A is supplied with the carrier signal directly from the sine wave generator 7. The multiplier 5B is supplied with the carrier signal shifted in phase by π/2 in a phase shifter 6. Thus, quadrature demodulation is conducted.

Here, a sine wave signal supplied to the multiplier 5A is represented as cos(ωt), and a sine wave signal supplied to the multiplier is represented as sin(ωt), where ω=2 πf.

Signals Im and Qm respectively of the in-phase component (I component) and the quadrature component (Q component) are subject to waveform shaping respectively in roll-off filters 8A and 8B, and then taken out as output signals Ir and Qr, respectively.

The output signals Ir and Qr are respectively supplied to delay circuits 27A and 27B, provided with predetermined delay τ, and output to an automatic equalizer 9 for data reproduction respectively as delay output signals IrD and QrD. The predetermined delay time τ is set to time required for transmission of data of one frame, i.e., the sum of time (transmission time tt) required for transmitting the training signal DT once and time (transmission time td) required for transmitting the data signal DA. In other words, τ=tt+td.

Data signals Ia and Qa equalized by the automatic equalizer 9 for data reproduction are input to a decision unit 10. In the decision unit 10, a transmission point sent from the transmission apparatus side is judged. A result of this judgement is output as data signals Id and Qd. The data signals Id and Qd are converted to a serial signal by a P/S converter 11. Demodulated reproduced data is thus obtained.

Heretofore, operation of the configuration ranging from the analog BPF 1 to the P/S converter 11 through the delay circuits 27A and 27B and the automatic equalizer 9 for data reproduction has been described. This operation is the same as the operation of the automatic equalization circuit according to the aforementioned U.S. Ser. No. 09/819,709.

Components relating to update processing of the tap coefficients for setting the equalization characteristic of the transmission path will now be described. Operation of an automatic equalizer 23 for equalization training, adders 16A and 16B, a training signal synchronization detector 12′, a tap coefficient update unit 13′, memories 21 and 22, and a switch 25 is the same as the operation of counterparts in the automatic equalization circuit according to the aforementioned U.S. Ser. No. 09/819,709, except points described below. However, the memories 21 and 22 operate so as to store both the training signal and the data signal of received data. The tap coefficient update unit 13′ conducts tap coefficient update processing even when an output signal C2 of a counter circuit 30 described later is received.

There is a difference in that there is provided a training pattern signal generator 29 for generating a reference training pattern signal P, which is used as the reference signals It and Qt when tap coefficient update processing is conducted by using the training signal of the received data.

There is a difference in that there is provided a decision unit 31 for judging output signals Ia′ and Qa′ of the automatic equalizer 23 for equalization training and outputting a judged signal D. As the decision unit 31, a decision unit having the same configuration as that of the decision unit 10 can be used.

There is a difference in that there is provided a selection circuit 28. When conducting the tap coefficient update processing by using the training signal of the received data, the selection circuit 28 selects and outputs the reference training pattern signal P of the training pattern signal generator 29. After the tap coefficients have been determined by using the training signal of the received data, the selection circuit 28 selects and outputs the judged signal D of the identifying unit 31.

There is a difference in that there is provided a counter circuit 30. The counter circuit 30 generates a signal C1, which indicates whether the tap coefficient update processing is being conducted on the basis of the training signal or the data signal of the received data. After the tap coefficients have been determined by using the training signal of the received data, the counter circuit 30 generates a signal C2 every N symbols of the received data. According to the signal C1 of the counter circuit 30, an output of the selection circuit 28 is connected to a (1) side to supply the reference training pattern signal P to a mapping circuit 32, or the output of the selection circuit 28 is connected to a (2) side to supply the identification signal D of the identifying unit 31 to the mapping circuit 32.

There is a difference in that there is provided a switch control circuit 33, which conducts ON/OFF control of the switch circuit 25. Upon receiving an output signal S2 of the training signal synchronization detector 12′ at the time of operation of the tap coefficient update processing using the training signal of the received data, the switch control circuit 33 sends the output signal S2 to the switch circuit 25 as a control signal. After the tap coefficient update processing using the training signal has been terminated, however, the switch control circuit 33 generates an ON/OFF control signal of the switch circuit 25 on the basis of the output signal C2 of the counter circuit 30. Such control signals are supplied to the switch circuit 25. As a result, tap coefficients set in the automatic equalizer 23 for equalization training on the basis of the training signal of the received data, and tap coefficients updated every N symbols after the tap coefficient setting based on the training signal can be set in the automatic equalizer 9 for data reproduction.

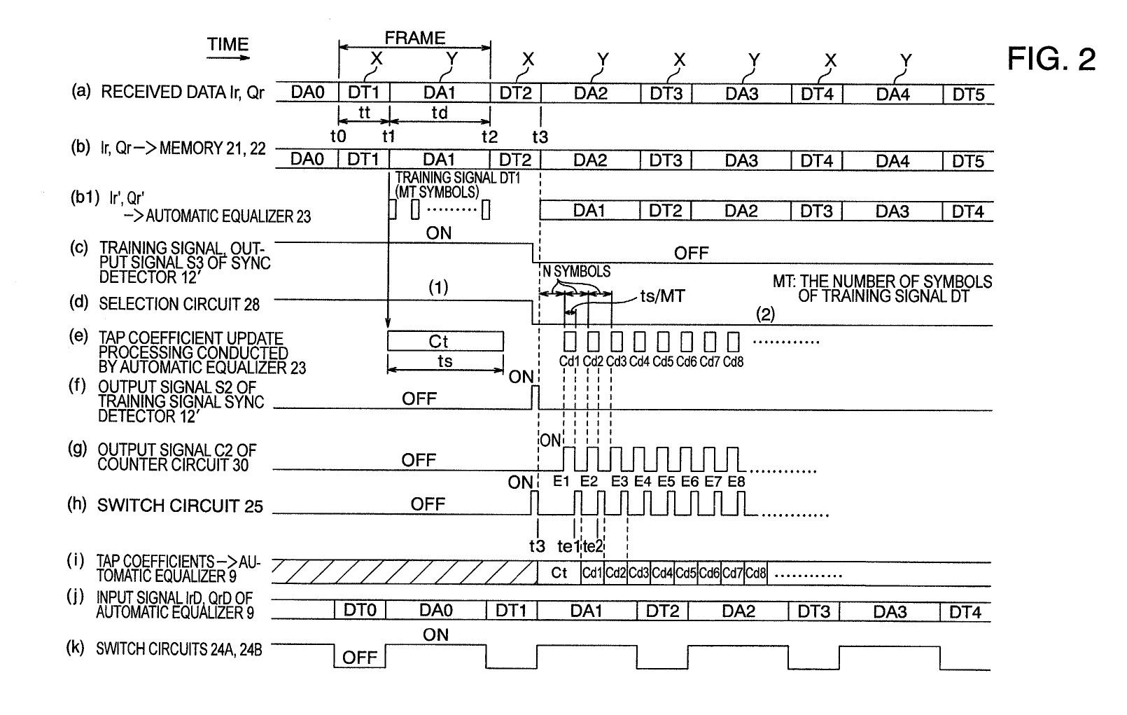

Operation of the embodiment shown in FIG. 1 will now be described by referring to a timing chart of FIG. 2.

In application of the automatic equalization circuit according to the present embodiment, the transmission side apparatus transmits the training signal DT in the period tt and the data signal DA respectively in the period td, alternately and periodically as shown in (a) of FIG. 2 in the same way as U.S. Ser. No. 09/819,709. The training signal DT or the data signal DA are represented by the output signals Ir and Qr respectively of the roll-off filters 8A and 8B. A period X represents a period during which the training signal DT is transmitted. A period Y represents a period during which the data signal DA is transmitted.

The training signal DT and the data signal DA shown in (a) of FIG. 2 are provided with numbers 0, 1, 2, . . . So as to correspond thereto, the training signal DT and the data signal DA shown in (b), (b1) and (j) of FIG. 2 are also provided with numbers 0, 1, 2, . . . In (b), (b1) and (j) of FIG. 2, signals having the same number correspond to each other. In addition, the same holds true of tap coefficients Ct, Cd1, Cd2, . . . shown in (e) and (i) of FIG. 2 as well.

A data reception waiting state will now be described.

Since the training signal DT is in an undetected state in the training signal synchronization detector 12′, an output signal S1 becomes OFF and both switch circuits 24A and 24B are in the OFF states (switch open states). Furthermore, since both the output signal S2 and the output signal C2 of the counter circuit 30 are in the OFF states, the switch control circuit 33 generates an output signal of OFF and turns the switch circuit 25 OFF. In addition, in the data reception waiting state, the output signal C1 of the counter circuit turns ON and the output of the selection circuit 28 is connected to the (1) side.

If data transmission operation is started from the transmission side apparatus in the state heretofore described, the training signal DT and the data signal DA are alternately received as shown in (a) of FIG. 2. Incidentally, here, to facilitate understanding, description will be made on the assumption that signal transmission is started at time t0 as illustrated, and demodulation operation is started therefrom.

First, from the time t0, the output signals Ir and Qr respectively of the roll-off filters 8A and 8B are successively supplied to the delay circuits 27A and 27B, respectively, and stored in the memories 21 and 22, respectively. In addition, the output signals Ir and Qr are supplied to the training signal synchronization detector 12′.

Since the output signals Ir and Qr respectively supplied to the delay circuits 27A and 27B are output with a delay (=tt+td) corresponding to one frame, the output signals Ir and Qr currently stored are output respectively as the signals IrD and QrD from time t3 as shown in (a) and (j) of FIG. 2.

Next, following a period X during which the training signal DT is being received, in a period Y when the next data signal DA is being received, first, the tap coefficient update unit 13′ starts to operate at illustrated time t1. Then, as shown in (e) of FIG. 2, tap coefficient update processing is started in a period ts on the basis of an equalization error signal E (Ei, Eq) obtained as difference values respectively between equalized signals Ia′ and Qa′ and reference signals It and Qt. The equalized signals Ia′ and Qa′ are obtained by conducting equalization on signals Ir′ and Qr′ of a training signal DT1 respectively read out from the memories 21 and 22. The reference signals It and Qt are obtained by conducting signal mapping on the reference training pattern signal P of the training pattern signal generator 29.

Detailed operation of the tap coefficient update processing using the training signal will now be described.

The signals Ir′ and Qr′ of the training signal DT respectively read out from the memories 21 and 22 become equalized signals Ia′ and Qa′ as a result of equalization processing conducted in the automatic equalizer 23 for equalization training. On the other hand, the reference training pattern signal P supplied from the training pattern signal generator 29 to the mapping circuit 32 via the contact of the (1) side of the selection circuit 28 becomes the reference signals It and Qt mapped to the in-phase component (I component) and the quadrature component (Q component). Computation for obtaining difference values respectively between the equalized signals Ia′ and Qa′ and the reference signals It and Qt is executed in the adders 16A and 16B, respectively. Upon receiving the equalization error signal E (Ei, Eq) output from the adders 16A and 16B, tap coefficient update processing in the tap coefficient update unit 13′ and equalization processing in the automatic equalizer 23 for equalization training are executed every symbol of the training signal having MT symbols so as to obtain such tap coefficients as to minimize the equalization error signal E (Ei, Eq). When the processing time ts has elapsed, the equalization error signal is minimized and the tap coefficient update processing is terminated.

In addition, in this period Y, the switch circuits 24A and 24B are turned ON as shown in (k) of FIG. 2. Thus, the equalized signals Ia and Qa of the automatic equalizer 9 for data reproduction are supplied directly to the decision unit 10, and judged signals Id and Qd are obtained. As a result, data reproduced from the data signal DA0 from the time t1 is outputted from the P/S converter 11.

At this time, however, tap coefficients corresponding to the transmission path characteristic are not set as shown in (i) of FIG. 2. Therefore, suitable equalization processing is not conducted. Thus, the reproduced data for the data signal DA0 is low in reliability.

Then, at time t3, that is, at a time after the transmission of the training signal DT2 from the time t2 is terminated and immediately before the next period Y starts, the output signal S2 is supplied to the switch control circuit 33 as a pulse signal from the training signal synchronization detector 12′ shown in (f) of FIG. 2. As a result, the switch circuit 25 is closed for a short time as shown in (h) of FIG. 2. By this time t3, however, updating of the tap coefficients by use of the automatic equalizer 23 for equalization training has been finished as shown in (e) of FIG. 2. The updated tap coefficients are represented by Ct as shown in (e) of FIG. 2.

As described above, the switch circuit 25 is closed for a short time immediately before the time t3 as shown in (h) of FIG. 2. At this time, together with the output of the output signal S2 of the training signal synchronization detector 12′, an output signal S3 is changed from its ON state to its OFF state as shown (c) of FIG. 2. Upon receiving the state change of the output signal S3, the tap coefficient update unit 13′ sets the updated tap coefficients Ct in the automatic equalizer 23 for equalization training. In addition, an update signal representing the tap coefficients Ct is sent to the automatic equalizer 9 for data reproduction via the switch circuit 25 closed for a short time, and the tap coefficients Ct are set in the automatic equalizer 9 for data reproduction as well (initial setting).

Immediately before the time t3, the output signal S3 of the training signal synchronization detector 12′ is changed from the ON state to the OFF state as shown (c) of FIG. 2. Upon receiving the output signal S3, the training pattern signal generator 29 and the counter circuit 30 operate as hereafter described after the time t3.

In the training pattern signal generator 29, generation of the reference training pattern signal P is stopped.

The counter circuit 30 switches over the input of the selection circuit 28 to the (2) side so as to be capable of accepting the output signal of the identifying unit 31 by using its output signal C1. The counter circuit 30 has the judging operation in the decision unit 31 started. In addition, the counter circuit 30 outputs an output signal C2 (E1, E2, . . . ) every N symbols as shown in (g) of FIG. 2.

Hereafter, operation conducted after the time t3 shown in FIG. 2 will be described.

In a period Y after the time t3, the switch circuits 24A and 24B are turned ON by the output signal S1 of the training signal synchronization detector 12′. At this time, as shown in (i) and (j) of FIG. 2, the data signal DA1 of the received data subjected to a one-frame delay is subject to equalization processing in the automatic equalizer 9 for data reproduction, by using, first the tap coefficients Ct updated on the basis of the above described training signal, and thereafter the tap coefficients (Cd1, Cd2, . . . ) updated every N symbols described later, and output as equalized signals Ia and Qa. The equalized signals Ia and Qa are supplied to the decision unit 10 via the switch circuits 24A and 24B to become the judged signals Id and Qd. The judged signals Id and Qd are output from the P/S converter 11 as reproduced data of the data signal DA of the received data.

Update operation of the first tap coefficients Ct from the time t3 and subsequent tap coefficients Cd1, Cd2, . . . updated every N symbols of the received data will now be described.

As represented by Ct in (i) of FIG. 2, the tap coefficient Ct is set in the automatic equalizer 9 for data reproduction at the time t3. The tap coefficient Ct has been obtained as a result of tap coefficient update processing based on the training signal DT1 and the reference training pattern signal P of the training pattern signal generator 29 serving as the reference signal. The tap coefficient Ct remains set in the automatic equalizer 9 for data reproduction until a second pulse signal output by the switch control circuit 33 in response to the output signal C2 of the counter circuit 30 turns OFF as shown in (h) of FIG. 2.

When a second pulse signal shown in (h) of FIG. 2 turns OFF, the tap coefficient Cd1 shown in (e) of FIG. 2 is set in the automatic equalizer 9 for data reproduction. The tap coefficient Cd1 has been obtained from the current tap coefficient Ct by tap coefficient update processing conducted once every N symbols of the received data. The tap coefficient Cd1 remains set in the automatic equalizer 9 for data reproduction until the next (a third) pulse signal turns OFF as shown in (h) of FIG. 2. Thereafter, as the time elapses, the current tap coefficient is updated every N symbols to tap coefficients Cd2, Cd3, . . . and these tap coefficients are set.

Operation conducted until the tap coefficients are set will now be described.

The signals Ir′ and Qr′ read out from the memories 21 and 22 as the data signal DA1 of the received data from the time t3 are supplied to the automatic equalizer 23 for equalization training, in the wake of the training signal DT1. The signals Ir′ and Qr′ of N symbols are read out from the memories 21 and 22, and supplied to the automatic equalizer 23 for equalization training. Simultaneously therewith, a pulse signal E1 is generated as the output signal C2 of the counter circuit 30 as shown in (g) of FIG. 2. A generation period of the pulse signal E1 is ts/MT, where MT is the number of symbols of the training signal DT of the received data, and ts is the processing time of the tap coefficient update.

Upon receiving the pulse signal E1 of the output signal C2, the tap coefficient update unit 13′ conducts tap coefficient update processing once on the basis of the equalization error signal E (Ei, Eq) and the current tap coefficient Ct. The equalization error signal E (Ei, Eq) has been obtained by the adders 16A and 16B from an Nth symbol of the above described signals Ia′ and Qa′, and the reference signals It and Qt obtained by judging the signals Ia′ and Qa′ in the decision unit 31 and conducting signal mapping on the judged signals in the mapping circuit 32. Thus, new tap coefficients Cd1 as shown in (e) of FIG. 2 are obtained.

Simultaneously with termination of the tap coefficient update processing, the pulse signal E1 of the output signal C2 of the counter circuit 30 changes from ON to OFF. At the same time, upon receiving the state change of the output signal C2, the switch control circuit 33 generates a pulse signal and thereby turns the switch circuit 25 ON for a short time as shown in (h) of FIG. 2. At this time, the updated tap coefficients Cd1 are newly set in the automatic equalizer 23 for equalization training. In addition, the tap coefficients Cd1 are newly set in the automatic equalizer 9 for data reproduction as shown in (i) of FIG. 2.

As shown in (h) and (i) of FIG. 2, the tap coefficient Cd1 is effective until the time when a pulse signal which turns the switch circuit 25 ON at time te2 is terminated and update coefficients Cd2 are set.

In this period, on the basis of the tap coefficients Cd1, the data signal DA1 is output from the automatic equalizer 9 for data reproduction as equalized signals Ia and Qa subjected to equalization processing. The equalized signals Ia and Qa are subject to identification processing and reproduced as identified signals Id and Qd. The reproduced data are output from the P/S converter 11.

At the time te1 when the first tap coefficient update processing after elapse of first N symbols is terminated, a first symbol and subsequent symbols of second N symbols have already been supplied to the automatic equalizer 23 for equalization training. Thereafter, at time when an Nth symbol is supplied, a pulse signal E2 of the output signal C2 of the count circuit 30 is generated as a pulse signal serving as start timing of second tap coefficient update processing as shown in (g) of FIG. 2.

Upon receiving the pulse signal E2 of the output signal C2, the tap coefficient update unit 13′ conducts tap coefficient update processing once on the basis of the equalization error signal E (Ei, Eq) and the current tap coefficient Cd1. The equalization error signal E (Ei, Eq) has been obtained from equalization signals Ia′ and Qa′ of the Nth symbol, and the reference signals It and Qt of the identified signal D. Thus, new tap coefficients Cd2 as shown in (e) of FIG. 2 are obtained. Simultaneously with termination of the tap coefficient update processing, the pulse signal E2 of the output signal C2 changes from ON to OFF. The tap coefficient update unit 13′ sets update tap coefficients Cd2 in the automatic equalizer 23. In addition, the switch circuit 25 turns ON for a short time under the control of the switch control circuit 33, and the tap coefficients Cd2 are set in the automatic equalizer 9 as well.

By using the new tap coefficients Cd2, the data signals are subject to equalization processing. Equalized signals Ia and Qa are subject to decision processing and reproduced as judged signals Id and Qd. The reproduced data are output from the P/S converter 11.

As in a series of processing operations heretofore described, tap coefficient update at a rate of once every N symbols of received data is repeated by using the current tap coefficients. In a period Y of the data signal DA of the received data, the switch circuits 24A and 24B turn ON. Data of the data signal subjected to equalization processing in the automatic equalizer 9 for data reproduction having tap coefficients set so as to correspond to the latest transmission path characteristic are reproduced, and output from the P/S converter 11.

By the way, when receiving the first training signal DT1 and thereby conducting the tap coefficient update processing, tap coefficient update is not conducted by using the reference signals It and Qt obtained by mapping the identified signal D of the decision unit 31. The reason is as follows: in such a state that equalization of the transmission path characteristic is not conducted, the equalization error E (Ei, Eq) is very large; in judgement or decision, the threshold is exceeded; and a correct equalization error E (Ei, Eq) cannot be obtained. Once tap coefficients have been determined by using the training signal DT, the equalization error E (Ei, Eq) is very small. Even in the case of a multilevel modulation signal such as 16 QAM or 64 QAM, the decision threshold is not exceeded. Once tap coefficients have been determined by using the training signal DT, tap coefficient update using the reference signals It and Qt obtained by mapping the judged signal D of the decision unit 31 becomes possible.

In the foregoing description, the delay time of each of the delay circuits 27A and 27B is set to the transmission time corresponding to one frame. Depending upon the relation between the frame length and the update processing time of the tap coefficients, however, the delay time must be set to two frames or more in some cases. In such a case, the delay time of the delay circuits 27A and 27B may be set to the time.

In the automatic equalization circuit of U.S. Ser. No. 09/519,709, equalization for the transmission path characteristic is conducted in tap coefficient update processing of one frame period by using the training signal DT. Therefore, characteristic changing of the transmission path occurring before the next training signal cannot be coped with, and the received data error probability of the reproduced data becomes high. According to the present embodiment, however, once equalization for the transmission path characteristic is completed by using the training signal DT, tap coefficient update processing is conducted every N symbols, which is shorter than the time length of one frame of the prior technique. As a result, transmission path changing can be coped with by faster equalization, and reliable reproduced data with data errors suppressed can be obtained.

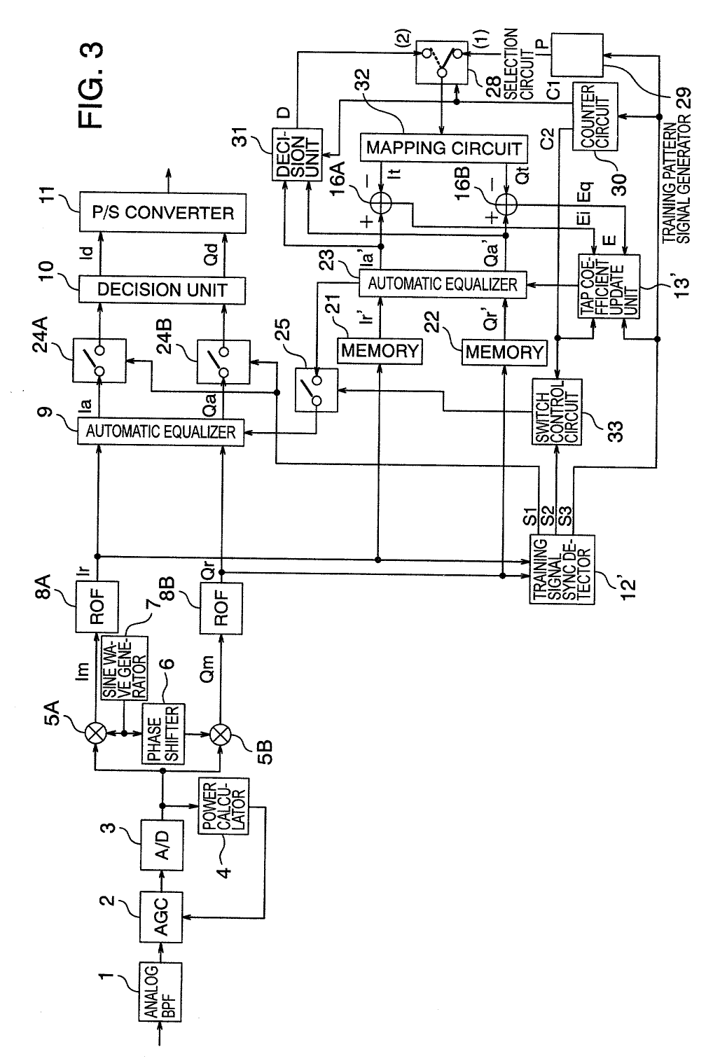

A second embodiment of the present invention will now be described by referring to FIG. 3.

In the embodiment of FIG. 3, the delay circuits 27A and 27B inserted between the roll-off filters 8A and 8B and the automatic equalizer 9 for data reproduction shown in FIG. 1 of the first embodiment are eliminated for simplifying the circuit. Remaining configuration is the same as that of FIG. 1 of the first embodiment.

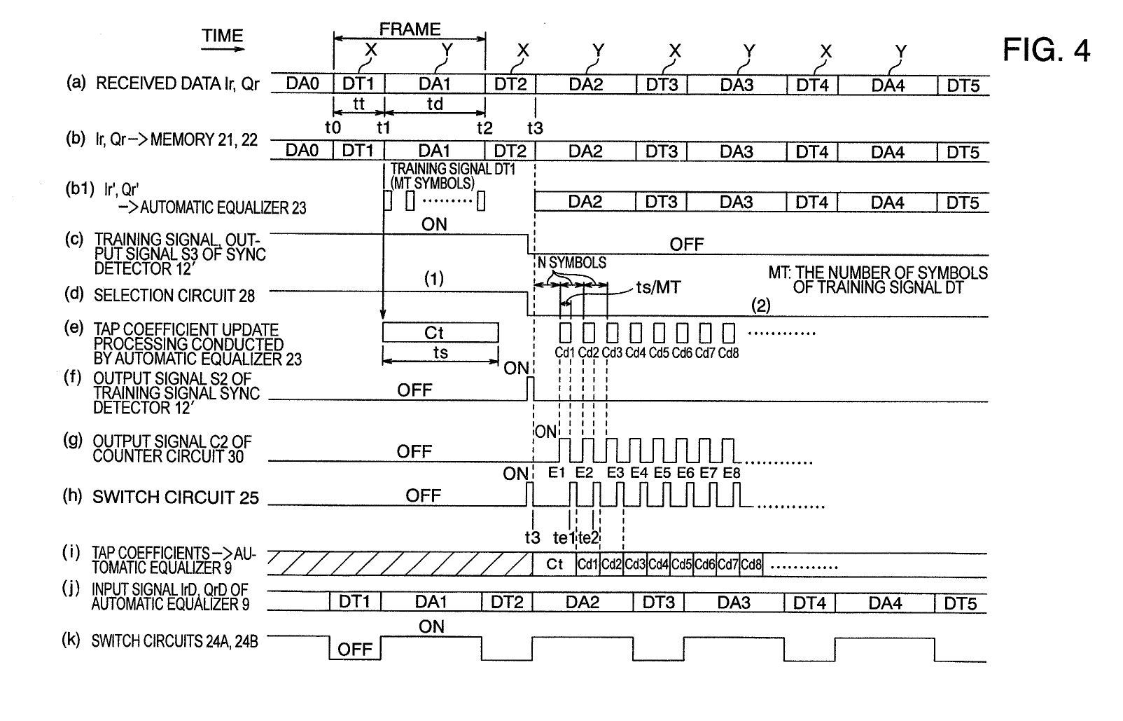

Operation of the embodiment shown in FIG. 3 will now be described by referring to a timing chart shown in FIG. 4.

The timing chart of FIG. 4 differs from the timing chart of FIG. 2 showing the first embodiment in two points concerning data contents of (b1) and (j) of FIG. 4.

A first difference is found in (j) of FIG. 4. In the first embodiment, the delay circuits 27A and 27B are placed between the roll-off filters 8A and 8B and the automatic equalizer 9 for data reproduction as shown in FIG. 1. Since received data IrD and QrD each having a one-frame delay are thus obtained, data are reproduced by conducting equalization processing on the received data delayed by one frame in the first embodiment. In the present embodiment, however, the delay circuits 27A and 27B are removed. Therefore, demodulated received data Ir and Qr are supplied directly to the automatic equalizer 9 for data reproduction. As a result, received data which are currently demodulated are subject to equalization processing, and data are reproduced.

Secondly, in order to associate the result of the tap coefficient update with the received data according to the first difference, the signals Ir′ and Qr′ read out from the memories 21 and 22 and supplied to the automatic equalizer 23 for equalization training after the time t3 are started with the data DA1 received one frame earlier in the first embodiment as shown in (bl) of FIG. 2. In the present embodiment, however, the signals Ir′ and Qr′ are started with the received data DA2 which are currently demodulated as shown in (b1) of FIG. 4.

Except that the data to be subjected to the tap coefficient update processing and the equalization processing after the time t3 are the data which are currently being received, therefore, operation of the present embodiment is the same as that of the first embodiment. Therefore, description of the operation of the present embodiment will be omitted.

In the same way as the first embodiment, according to the second embodiment, the tap coefficient update processing is not conducted every frame period in which a training signal is received, unlike the prior technique. Once equalization of the transmission path characteristic is completed by using the training signal DT, the tap coefficient update processing of the automatic equalizer is conducted every time data of N symbols are received. Therefore, tap coefficients corresponding to a variation of the transmission path characteristic which has occurred by the time of reception of the next training signal are obtained. As a result, reproduction of reliable data becomes possible.

Furthermore, data reproduced by the equalization processing conducted on the data signal DA1 of the first received frame are not obtained. As for subsequent data signals, however, data reproduction with a time delay of one frame is not conducted unlike the first embodiment. Instead, data which are currently being received are successively reproduced. Therefore, the transmission delay can be suppressed. The second embodiment is thus suitable for real time transmission.

According to the present embodiment, once equalization for the transmission path characteristic is completed by using the training signal DT, tap coefficient update processing is conducted every N symbols. Therefore, it is possible to conduct equalization on the transmission path characteristic so as to follow the variation of the transmission path characteristic. An equalized state can always be achieved and error occurrence in the received data can be suppressed. As a result, it is possible to easily provide a digital multilevel signal demodulation circuit having high reliability in data reproduction.

If the operation rate of hardware is fast, then the tap coefficient update with N=1, i.e., every symbol of the received data becomes possible and the tracking property becomes extremely high. Thus the received data can be reproduced by conducting equalization while sufficiently following even a fast change of the transmission path characteristic. As a result, it is possible to easily provide a digital multilevel signal demodulation circuit having high reliability in data reproduction with data error occurrence further suppressed.

While the invention has been particularly described and shown with reference to the preferred embodiments thereof, it will be understood by those skilled in the art that various changes in form and detail and omissions may be made therein without departing from the spirit and scope of the invention.

For example, in FIGS. 1 and 3, the mapping circuit 32 is provided independently. Alternatively, it is also possible to incorporate the mapping circuit in each of the training pattern signal generator 29 and the identifying unit 31, and supply the reference signals It and Qt from the selection circuit 28 to the adders 16A and 16B, respectively.

1. An automatic equalization method for automatically updating an equalization characteristic required to demodulate a received signal including a training signal of a predetermined pattern transmitted from a transmitter, said automatic equalization method comprising the steps of:
initial-setting tap coefficients of a first automatic equalizer for data reproduction based on said received training signal;
updating said tap coefficients once every N symbols (where N is a positive integer except O) of said received signal based on said received signal; and
equalizing said received signal in said first automatic equalizer based on said updated tap coefficients.

2. An automatic equalization method according to claim 1, wherein said initial-setting step comprises the step of obtaining tap coefficients of a second automatic equalizer for equalization training based on said training signal of said predetermined pattern and a reference training signal of a pattern which is substantially identical with said training signal of said predetermined pattern and which is generated on a receiver, and the step of setting said tap coefficients of said first automatic equalizer based on said tap coefficients of said second automatic equalizer.

3. An automatic equalization method according to claim 2, wherein said tap coefficients of said second automatic equalizer is updated once every N symbols (where N is a positive integer except O) of said received signal based on said received signal, and said tap coefficients of said first automatic equalizer is updated based on said updated tap coefficients of said second automatic equalization.

4. An automatic equalization method according to claim 2, wherein said tap coefficients of said second automatic equalizer is updated once every N symbols (where N is a positive integer except O) of said received signal based on equalized signals obtained by equalizing said received signal in said second automatic equalizer and identified signals obtained by identifying said equalized signals in a decision unit.

5. An automatic equalization method according to claim 2, wherein said received signal is stored in a storage unit and then supplied to said second automatic equalizer.

6. An automatic equalization method according to claim 5, wherein said received signal is delayed by a delay unit and then supplied to said second automatic equalizer.

7. An automatic equalization method in an automatic equalization apparatus having a first automatic equalizer for data reproduction and a second automatic equalizer for equalization training, said automatic equalization method comprising the steps of:
receiving a transmission signal transmitted from a transmitter in a form of a frame including a training signal of a predetermined pattern and a data signal;
generating a first and a second reference signals for setting tap coefficients of said second automatic equalizer;
updating the tap coefficients of said second automatic equalizer based on said first and second reference signals and said received signal; and
equalizing said received signal in said first automatic equalizer based on said updated tap coefficients of said second automatic equalizer.

8. An automatic equalization method according to claim 7, wherein said first reference signal includes a reference training signal having a pattern which is substantially identical with that of said training signal, and said second reference signal includes an identified signal obtained by equalizing said received signal in said second automatic equalizer and judging resultant equalized signals in a decision unit.

9. An automatic equalization method according to claim 8, comprising the steps of:
setting said tap coefficients in said second automatic equalizer based on said received training signal and said reference training signal, and starting equalization of said received data in said first automatic equalizer having said set tap coefficients set therein; and
updating said tap coefficients of said second automatic equalizer once every N symbols (where N is a positive integer except o) of said received signal, based on said received signal and said judged signal, and equalizing said received signal in said first automatic equalizer updated with said updated tap coefficients.

10. An automatic equalization method according to claim 9, wherein said received signal is stored in a storage unit and supplied to said second automatic equalizer.

11. An automatic equalization method according to claim 10, wherein said received signal is delayed in a delay device by M frames (where M is a positive integer except o) and supplied to said automatic equalizer.

12. An automatic equalization circuit for receiving a training signal of a predetermined pattern and a data signal transmitted from a transmitter via a transmission path, as a received signal, and equalizing said received signal, said automatic equalization circuit comprising:
a first automatic equalizer for data reproduction for equalizing said received data signal;
a second automatic equalizer for equalization training having tap coefficients updated based on said training signal and said data signal and reference signals, said second automatic equalizer outputting an update signal for said updated tap coefficients in said first automatic equalizer;
a first reference signal generator for generating a first reference signal to be used for initial setting of said tap coefficients of said second automatic equalizer;
a second reference signal generator for generating a second reference signal to be used for updating said tap coefficients of said second automatic equalizer after said initial setting of said tap coefficients of said second automatic equalizer; and
a selector connected to said first and second reference signal generators to select an output of said first reference signal generator and an output of said second reference signal generator, for supplying the selected output to said second automatic equalizer;
wherein said tap coefficients of said first automatic equalizer are updated based on said tap coefficients of said second automatic equalizer.

13. An automatic equalization circuit according to claim 12, wherein said first reference signal generator comprises a training pattern signal generator for generating a reference training pattern signal having a pattern which is substantially identical with that of said training signal transmitted from said transmitter, and
said second reference signal generator comprises a decision unit for judging a signal obtained by equalizing said received signal in said second automatic equalizer.

14. An automatic equalization circuit according to claim 13, further comprising a controller for causing said selector to select the output of said first reference signal generator, causing said selector to select the output of said second reference signal generator after the tap coefficients of said second automatic equalizer are updated based on said training signal and said reference training pattern signal, and exercising control so as to update the tap coefficients of said second automatic equalizer once every N (where N is a positive integer except o) symbols of said received signal.

15. An automatic equalization circuit according to claim 13, further comprising a mapping circuit coupled between said selector and said second automatic equalizer,
wherein the tap coefficients of said second automatic equalizer are updated based on a mapped reference signal supplied from said mapping circuit and said received signal.

16. An automatic equalization circuit according to claim 13, wherein each of said training pattern signal generator and said decision unit includes a mapping circuit, and the tap coefficients of said second automatic equalizer are updated based on a mapped reference signal supplied from said selector and said received signal.

17. An automatic equalization circuit according to claim 12, further comprising memories for storing said received signal in order to supply said received signal to said second automatic equalizer.

18. An automatic equalization circuit according to claim 17, further comprising delay circuits for delaying said received signal in order to supply said received signal to said first automatic equalizer.

19. An automatic equalization circuit according to claim 18, wherein said received signal is a signal having a form of a frame including said training signal and a data signal, and said delay circuits delay said received data by M frames (where M is a positive integer except o).

20. A receiver circuit for reproducing a data signal from a received signal including a training signal and said data signal modulated by using a digital multilevel modulation system, said receiver circuit comprising:
a signal processing section for demodulating said received signal in order to generate a digital training signal and a digital data signal;
an automatic equalization circuit for receiving said digital training signal and said digital data signal from said signal processing section and equalizing said data signal;
a decision unit connected to an output of said automatic equalization circuit; and
a parallel/serial converter connected to an output of said decision unit to output said data signal,
wherein said automatic equalization circuit including:
a first automatic equalizer for receiving said digital data signal and equalizing said data signal; and
a second automatic equalizer having tap coefficients updated based on said digital training signal and said digital data signal, said second automatic equalizer outputting an update signal for updating tap coefficients of said first automatic equalizer, said second automatic equalizer conducting initial setting of the tap coefficients of said first automatic equalizer by using said training signal, and after the initial setting, said second automatic equalizer successively updating said tap coefficients once every N symbols (where N is a positive integer except o) of said received data by using said received data.

21. A receiver circuit according to claim 20, further comprising:
a first reference signal generator for generating a first reference signal to be used for initial setting of said tap coefficients of said second automatic equalizer;
a second reference signal generator for generating a second reference signal to be used for successively updating said tap coefficients of said second automatic equalizer after said initial setting of said tap coefficients; and
a selector coupled to said first and second reference signal generators to select either an output of said first reference signal generator or an output of said second reference signal generator in order to supply the selected output to said second automatic equalizer,
wherein said tap coefficients of said second automatic equalizer are updated based on said first reference signal, said second reference signal and said received data.

22. A receiver circuit according to claim 20, wherein said second automatic equalizer has a configuration which is substantially identical with that of said first automatic equalizer.

23. A receiver circuit according to claim 21, wherein said first reference signal generator comprises a training pattern signal generator for generating a reference training pattern signal having a pattern which is substantially identical with that of said training signal transmitted from a transmitter, and
said second reference signal generator includes an identifying unit for identifying a signal obtained by equalizing said training signal and data signal in said second automatic equalizer in order to generate a judged signal.

24. A receiver circuit according to claim 23, further comprising a controller for causing said selector to select the output of said first reference signal generator, causing said selector to select the output of said second reference signal generator after the tap coefficients of said second automatic equalizer are updated based on said training signal and said reference training pattern signal, and exercising control so as to update the tap coefficients of said second automatic equalizer once every N (where N is a positive integer except o) symbols of said training signal and data signal.

25. A receiver circuit according to claim 21, further comprising a mapping circuit coupled between said selector and said second automatic equalizer,
wherein the tap coefficients of said second automatic equalizer are updated based on a mapped reference signal supplied from said mapping circuit and said received data.

26. A receiver circuit according to claim 23, wherein each of said training pattern signal generator and said decision unit includes a mapping circuit, and the tap coefficients of said second automatic equalizer are updated based on a mapped reference signal supplied from said selector and said received data.
